(19) United States
(12) Patent Application Publication
(10) Pub. No.: US 2026/0255913 A1
(43) Pub. Date: Aug. 27, 2026

(54) SEMICONDUCTOR DEVICE MANUFACTURING SYSTEM, PROCESSING RESULT ESTIMATION METHOD, SEARCH METHOD, AND SERVER

(71) Applicant: HITACHI HIGH TECH CORPORATION, Tokyo (JP)

(72) Inventors: Naoto TAKANO, Hillsboro, OR (US); Kohei Matsuda, Tokyo (JP); Ryoji Asakura, Tokyo (JP)

(21) Appl. No.: 19/065,122

(22) Filed: Feb. 27, 2025

(51) Int. Cl. H01L 21/67; G06N 3/084

(52) U.S. Cl. CPC H10P 72/0604; G06N 3/084; H10P 72/0618

(57) ABSTRACT

A semiconductor device manufacturing system and method for estimating a processing result by inputting a parameter into a model corresponding to each step even though processing conditions have different numbers of steps or different step structures from processing conditions serving as training data, and including an application that executes a learning step of training model parameters of an integrated model obtained by integrating step models, and, by using the integrated model and training data, and estimating information about the processing result according to a desired processing condition using the trained integrated model, and outputting the estimated processing result, in which the integrated model outputs the information about a processing result by using a parameter value of the step corresponding to the step model as the input value, and the information about the processing result acquired in advance includes information about the processing result obtained by two or more steps.

### TECHNICAL FIELD

The present invention relates to a semiconductor device manufacturing system, a processing result estimation method, a search method, and a server in a semiconductor process.

### BACKGROUND ART

In a semiconductor process, desired semiconductor device processing is performed by setting appropriate processing conditions obtained by process development in a processing apparatus. Here, the process represents a process such as a film formation process, a lithography process, and an etching process, which are performed on a sample. The processing condition includes at least one or more items of control parameters of the processing apparatus.

In recent years, many new items have been added to the processing conditions due to introduction of new materials constituting the device and expansion of a control range of the apparatus in accordance with complexity of the device structure.

In order to sufficiently derive the performance of the processing apparatus, it is essential to optimize the processing conditions. Therefore, it is important to grasp a relationship between the parameters of the processing conditions and processing results, but the optimization of the processing conditions requires advanced knowledge due to the complexity of the processing conditions and device structures. Therefore, there is a problem of a lack of experts who can optimize processing conditions in the field of process development.

As a solution, a method of constructing a machine learning model that estimates a processing result from a processing condition has attracted attention. Specifically, training data is created from an experimental data group in which processing conditions are inputs and processing results are outputs, and a regression model is trained. Patent Document 1 is cited as the invention. An object of Patent Document 1 is to “supports a search for apparatus conditions of a manufacturing apparatus. In particular, to support a construction of a dataset for generating a model used for a search”, and the following contents are disclosed as a computer system and a method of supporting a search for apparatus conditions. “The computer system for supporting a search for an apparatus condition for controlling a manufacturing apparatus that performs processing receives an input of learning data including a combination of an input parameter value, which is an apparatus condition, and an output parameter value, which is a processing result, analyzes a structure of a manufacturing step of processing in standard learning data and a structure of a manufacturing step of processing in the other learning data, executes a classification process of specifying learning data which is aggregable with the same dataset as the standard learning data, generates a dataset based on results of the classification process, executes a learning process of a model using the dataset, searches for the input parameter value based on the model and a target value of the output parameter, and presents an interface for displaying search results”.

### CITATION LIST

### Patent Document

[Patent Document 1] Japanese Patent Application Laid-Open No. 2023-68859

### SUMMARY OF THE INVENTION

### Problem to be Solved by the Invention

However, the processing conditions in the semiconductor process are usually configured as a series of processes of a plurality of steps, and in the field of process development, processing conditions for achieving target processing are found through trial and error of changing the number or configuration of steps. Therefore, the experimental data group includes a mixture of processing conditions with different numbers of steps and different step configurations. Since linear regressions or kernel regressions, which are general regression models, cannot be used for learning unless the data size of the processing conditions to be used as an input is consistent, when the regression models are used, only data with the same number of steps and the same step configuration is extracted from the experimental data group and used for learning. When a plurality of data having the same data size cannot be extracted from the experimental data group, there may be a lack of training data that can be used for learning, so that it is difficult to obtain sufficient prediction accuracy (estimation accuracy). In addition, when an input/output relationship trained from experimental data is represented by a single regression model, it becomes difficult to extract only the learning results for some steps from the regression model, so that it is difficult to sufficiently secure reusability of the model.

Patent Document 1 discloses that “a classification process of specifying the training data, which is aggregable with the same dataset as the standard training data, is executed, a dataset is generated by aggregating the training data based on results of the classification process, and a learning process of a model that predicts the output parameter value from the input parameter value is executed using the dataset”. Therefore, although Patent Document 1 may cause the above-described problems, the problems are not sufficiently discussed in Patent Document 1.

Thus, an object of the present invention is to provide a technology that can estimate a processing result by inputting a parameter into a model corresponding to each step even though processing conditions have different numbers of steps or different step structures from processing conditions serving as training data.

### Means for Solving the Problems

In order to solve the above-described problems, one representative semiconductor device manufacturing system of the present invention is a semiconductor device manufacturing system including: a platform on which an application is implemented, the application using processing conditions of a semiconductor manufacturing apparatus, which are configured by at least one step, as an input and outputting information indicating an estimated value of a processing result obtained by the processing conditions, in which the application executes a learning step of training model parameters of an integrated model, which is a model obtained by integrating a step model and at least one step model that is a model in which a parameter value defined in the step is used as an input value, by using the integrated model and training data, an estimation step of estimating information about the processing result according to a desired processing condition using the trained integrated model, and an output step of outputting the estimated processing result, the integrated model outputs the information about the processing result by using a parameter value of the step corresponding to the step model as the input value, and the information about the processing result acquired in advance includes information about the processing result obtained by two or more steps.

### Advantageous Effect of the Invention

According to the present invention, it is possible to estimate a processing result by inputting a parameter to a model corresponding to each step even though processing conditions have different numbers of steps or different step structures from processing conditions serving as training data.

The problems, configurations, and effects other than those described above are clarified by the description in Modes for carrying out the Invention.

### BRIEF DESCRIPTION OF THE DRAWINGS

FIG. 1 is a block diagram illustrating an example of a configuration of a semiconductor device manufacturing system in Embodiment 1.

FIG. 2 is a diagram illustrating an example of processing conditions in Embodiment 1.

FIG. 3 is a diagram illustrating another example of the processing conditions in Embodiment 1.

FIG. 4 is a diagram illustrating an example of an integrated model in Embodiment 1.

FIG. 5 is a diagram illustrating an example of an integration method when the number of steps of the processing condition and the number of steps of the integrated model are different in Embodiment 1.

FIG. 6 is a diagram illustrating still another example of the integrated model in Embodiment 1.

FIG. 7 is a diagram illustrating a flowchart of a process performed by the semiconductor device manufacturing system of Embodiment 1.

FIG. 8 is a block diagram illustrating an example of a configuration of a semiconductor device manufacturing system in Embodiment 2.

FIG. 9 is a diagram illustrating an example of processing conditions in Embodiment 2.

FIG. 10 is a diagram illustrating another example of the processing conditions in Embodiment 2.

FIG. 11 is a diagram illustrating an example of pre-processing of the processing conditions in Embodiment 2.

FIG. 12 is a diagram illustrating another example of the pre-processing of the processing conditions in Embodiment 2.

FIG. 13 is a diagram illustrating an example of an integrated model in Embodiment 2.

FIG. 14 is a diagram illustrating another example of the integrated model in Embodiment 2.

FIG. 15 is a diagram illustrating a flowchart of a process performed by the semiconductor device manufacturing system of Embodiment 2.

FIG. 16 is a block diagram illustrating an example of a configuration of a semiconductor device manufacturing system in Embodiment 3.

FIG. 17 is a diagram illustrating an example of a target step in Embodiment 3.

FIG. 18 is a diagram illustrating an example of a reference step in Embodiment 3.

FIG. 19 is a diagram illustrating an example of processing conditions of the target step in Embodiment 3.

FIG. 20 is a diagram illustrating an example of processing conditions of the reference step in Embodiment 3.

FIG. 21 is a diagram illustrating a flowchart of a process performed by the semiconductor device manufacturing system of Embodiment 3.

FIG. 22 is a diagram illustrating an example of a GUI for presenting an estimation result to a user in an estimation result output unit.

FIG. 23 is a diagram illustrating an example of a GUI for the user to assign a label by the label assignment unit.

FIG. 24 is a diagram illustrating another example of the GUI for the user to assign a label by a label assignment unit 1102.

FIG. 25 is a diagram illustrating an example of a GUI for searching and selecting a reference step model to be referenced from a reference model database.

FIG. 26 is a diagram illustrating another example of the GUI for searching and selecting the reference step model to be referenced from the reference model database.

FIG. 27 is a diagram illustrating an example of a hardware configuration of the semiconductor device manufacturing system of Embodiment 3.

### MODES FOR CARRYING OUT THE INVENTION

Hereinafter, embodiments of the present invention will be described with reference to the accompanying drawings. However, the present invention is not interpreted to be limited to the description of the embodiments set forth below. It would be easily understood by those skilled in the art that a specific configuration of the present invention can be modified without departing from the concept or spirit of the present invention.

Positions, sizes, shapes, and the like of respective configurations illustrated in the drawings and the like of the present specification may not represent actual positions, sizes, shapes, and the like in order to easily understand of the invention. Therefore, the present invention is not limited to the positions, sizes, shapes, and the like disclosed in the drawings and the like.

In the present disclosure, the step of the processing condition means a processing condition associated with each of a series of processes obtained by dividing the series of processes in time series when the series of processes is performed based on the processing condition. For example, the step of the processing condition refers to a setting condition of the processing apparatus that is switched in time series when the series of processes based on the processing condition is performed by the processing apparatus.

### Embodiment 1

As Embodiment 1, an example of a semiconductor device manufacturing system that estimates a processing result such as a critical dimension (CD) or an etch depth in a plasma etching process will be described. The semiconductor device manufacturing system can execute a processing result estimation method of estimating a processing result. However, the present disclosure is not limited to the processing type and the processing content. The present disclosure can be applied to a semiconductor device manufacturing apparatus, but the semiconductor device manufacturing apparatus includes, for example, a lithography apparatus, a film forming apparatus, a pattern processing apparatus, an ion implantation apparatus, a heating apparatus, a washing apparatus, and the like, in addition to the plasma etching processing apparatus. Examples of the lithography apparatus include an exposure apparatus, an electron beam drawing apparatus, an X-ray drawing apparatus, and the like. Examples of the film forming apparatus include a chemical vapor deposition (CVD) apparatus, a physical vapor deposition (PVD) apparatus, a vapor deposition apparatus, a sputtering apparatus, a thermal oxidation apparatus. Examples of the pattern processing apparatus include a wet processing apparatus, a dry processing apparatus, an electron beam processing apparatus, a laser processing apparatus, and the like. Examples of the ion implantation apparatus include a plasma doping apparatus and an ion beam doping apparatus, and the like. Examples of the heating apparatus include a resistance heating apparatus, a lamp heating apparatus, a laser heating apparatus, and the like. Examples of the washing apparatus include a liquid washing apparatus, an ultrasonic washing apparatus, and the like.

### (Configuration and Process of System)

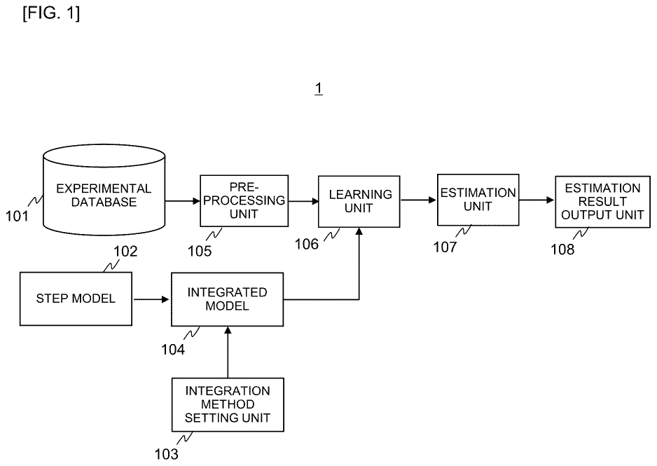

FIG. 1 is a block diagram illustrating an example of a configuration of a semiconductor device manufacturing system 1 in Embodiment 1. The semiconductor device manufacturing system 1 includes a platform on which an application is implemented, in which the application uses processing conditions of a semiconductor manufacturing apparatus, which are configured by at least one step, as an input and outputs information indicating an estimated value of a processing result obtained by the processing conditions. Specifically, the semiconductor device manufacturing system 1 includes an experimental database 101, a step model 102, an integration method setting unit 103, an integrated model 104, a pre-processing unit 105, a learning unit 106, an estimation unit 107, and an estimation result output unit 108. Each component included in the semiconductor device manufacturing system 1 is connected to each other directly or through a network. Each component may be realized by hardware or may be realized as software (application). When each component is realized as an application, the application may be implemented on a platform in which software and hardware are integrated, and the semiconductor device manufacturing system 1 may include the platform. A function of each component is realized by executing the application on the platform. In addition, the semiconductor device manufacturing system 1 may be a server on which the application is implemented and which executes the application. The semiconductor device manufacturing system 1 may include a manufacturing processing apparatus for a semiconductor device, and information used in the manufacturing processing apparatus may be stored in the experimental database 101. The semiconductor device manufacturing system 1 estimates, for example, a processing result derived from a processing condition designated by a user, but in some cases, the processing condition designated by the user is referred to as a first processing condition, and the processing result, which is the estimation result, is referred to as a first processing result. In addition, the processing condition and the processing result stored in the experimental database 101, which will be described later, may be referred to as a second processing condition and a second processing result, respectively, and may be described separately.

The experimental database 101 stores data including information about the second processing condition, which is a processing condition acquired in advance, and information about the second processing result processed based on the second processing condition. In addition, in the experimental database 101, the information about the processing result acquired in advance includes information about a processing result obtained by two or more steps. The experimental database 101 includes information about a processing result obtained by measurement after two or more steps are continuously processed. Specifically, the experimental database 101 is a database in which data indicating processing conditions and processing results acquired by performing evaluation such as measurement on a processing target (in the present disclosure, a semiconductor wafer) that is processed based on the processing conditions are stored. Generally, the processing conditions include several steps. However, the processing conditions included in the experimental database 101 are not limited to processing conditions having the same number of steps and the same step configuration, and the processing conditions may have different numbers of steps and different step configurations. In addition, the information about a processing target material may be included in each step of the processing condition.

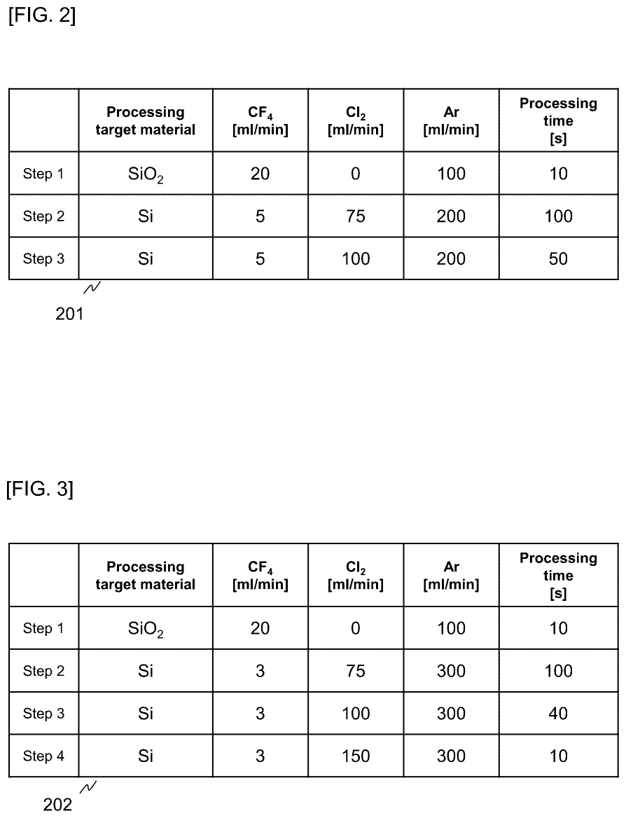

FIG. 2 is a diagram illustrating an example of processing conditions in Embodiment 1. The processing condition 201 includes three steps of Step (hereinafter, referred to as a “step”) 1 to step S3. As items, the processing condition 201 includes “processing target material”, “CF₄ [ml/min]”, “Cl₂ [ml/min]”, “Ar [ml/min]”, and “processing time [s]”. The item “processing target material” is information about a processing target material indicating a material of a semiconductor wafer obtained by performing a plasma etching process, in which Si, which is a material of a silicon substrate, and SiO₂, which is a material of a film formed on the silicon substrate, are represented. The items “CF₄ [ml/min]”, “Cl₂ [ml/min]”, and “Ar [ml/min]” indicate flow rates of gases introduced into a plasma processing apparatus, respectively. The item “processing time [s]” indicates a time from a start of supply of the gas to a stop of supply of the gas. As will be described later, values of the items are treated as parameters when pre-processing is performed. In addition, for the sake of simplicity, the item “CF₄ [ml/min]” is represented as “CF₄” without the unit. The same applies to other items.

In addition, FIG. 3 is a diagram illustrating another example of the processing conditions in Embodiment 1. The processing condition 202 includes four steps of step 1 to step 4. The processing condition 201 of FIG. 2 and the processing condition 202 of FIG. 3 have different numbers of steps, but both are stored in the experimental database 101.

Regarding the processing target that has been subjected to the plasma etching process based on the processing conditions, a CD, an etch depth, or the like is measured. The processing result, which is data indicating a measurement result, is stored in the experimental database 101 in association with each of the processing condition 201 and the processing condition 202. The processing result may be set for each processing condition, or may be set for each step of the processing condition. In addition, the present invention is not limited to a case where the processing result is set for all the steps included in the processing condition, and there may be a step in which the processing result is not set. In addition, the processing result may include a plurality of items, such as CDs or etch depths.

Although a case in which the processing condition includes five items is described, the present disclosure is not limited to the case. The processing condition may include other items, or may include other items in a case of a process other than the plasma etching process. In addition, the processing result can also be set according to the type of processing to be performed, as in the case of the processing condition. In addition, the data stored in the experimental database 101 may be experimental data acquired by an experiment or data acquired through the plasma etching process.

The description will be made with reference to FIG. 1. The pre-processing unit 105 executes pre-processing on the data stored in the experimental database 101 to create training data. The training data is generated by performing the pre-processing on data including information about the processing condition and information about the processing result acquired in advance (training data generation step). The pre-processing method includes a process of selecting and/or omitting a parameter included in the processing condition, a process of scaling a parameter value included in the processing condition, and the like. The former includes a process in which, when a parameter set that has perfect correlation through all processing conditions exists, one parameter of the parameter set is left and other parameters are deleted, a process in which, when a parameter that has an invariant value through all processing conditions exists, the parameter is deleted, or the like. The latter includes a scaling process such that an average of each parameter is 0 and variance is 1 through all processing conditions, a scaling process such that Max is 1 and Min is 0, and the like. The pre-processing unit 105 performs pre-processing on a plurality of processing conditions having different numbers of steps or different step structures to create training data.

The step model 102 is a model (hereinafter, referred to as a “step model”) in which a parameter value defined in each step is used as an input value. The step model 102 may be a single step model or a plurality of step models (one or more step models). The step model 102 is trained by the learning unit 106 as described later. The step model 102 includes a value of an item of a processing condition for each step in an input and includes an item of a processing result in an output. As shown in Embodiment 2, the step model may include information about the processing target material in the step as an input value.

The integration method setting unit 103 sets or changes an integration method in the integrated model 104 to be described later. The integration method setting unit 103 sets the integration method when step models 102 are integrated to generate one integrated model 104. In the integration method setting unit 103, the integration method of the step model is set or the integration method of the step model is changed (integration method setting and/or changing step).

The integrated model 104 is a model in which one or more step models are integrated, and is created according to the integration method set by the integration method setting unit 103. The integrated model 104 outputs information about the processing result by using the parameter value of the step corresponding to the step model as an input value. For example, the integrated model 104 uses parameter values of the series of steps corresponding to each of one or more step models (step models 102) as input values, and outputs information about the processing result when the semiconductor wafer is processed based on the series of steps. The integration method will be described later.

The learning unit 106 trains model parameters of an integrated model, which is a model obtained by integrating a step model and at least one step model, by using the integrated model and the training data (learning step). For example, the learning unit 106 trains the model parameters of the integrated model by using the training data such that the output of the integrated model 104 is (consistent with) the processing result. For example, when each of the step models 102 included in the integrated model 104 is a neural network, the learning unit 106 trains the model parameters of the integrated model 104 by an error backpropagation method. Even if the model is not a neural network model, but is a parametric model, learning is executed by obtaining, for example, model parameters that minimize a generalization error estimated using the training data through numerical calculation or the like.

The estimation unit 107 estimates information about a processing result according to a desired processing condition (first processing condition) using the trained integrated model 104 (estimation step). Specifically, the estimation unit 107 can receive, for example, the desired processing condition of the user, and estimates a processing result reached when the plasma etching process is performed according to the desired processing condition by inputting the desired processing condition of the user into the trained integrated model 104.

The estimation result output unit 108 outputs the processing result (first processing result) estimated by the estimation unit 107 (output step), and presents the processing result to the user of the semiconductor device manufacturing system 1.

### (Example of Integration Method)

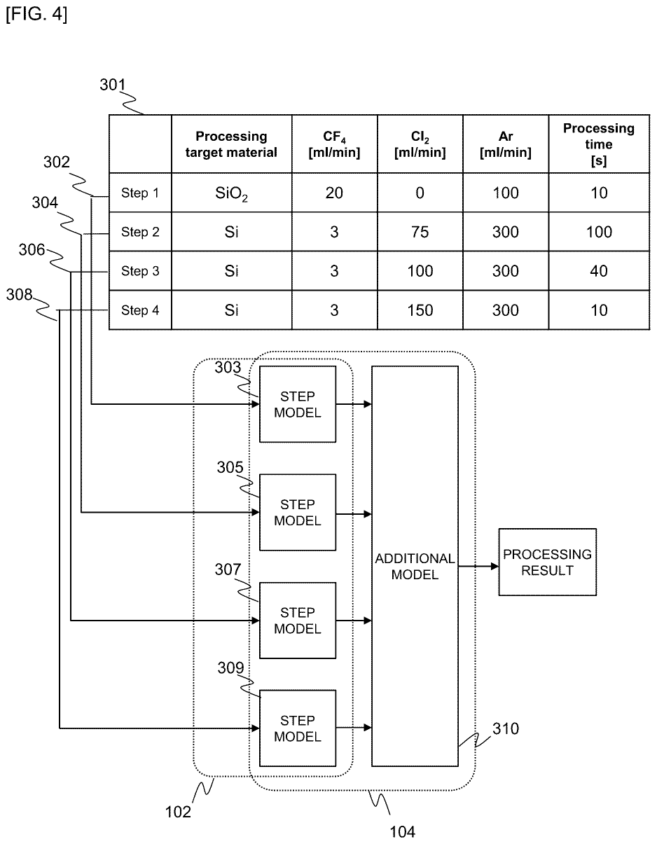

The integration method in Embodiment 1 will be described with reference to FIGS. 4 to 6. An additional model that is a model different from the step model is generated by the integration method setting and/or changing step, in which the integration method is an integration method in which an output of the step model is used as an input of the additional model, and the model parameters of the integrated model are trained such that an output of the additional model is information of the processing result. FIG. 4 is a diagram illustrating an example of the integrated model 104 in Embodiment 1. In the integration method illustrated in FIG. 4, the integration method setting unit 103 generates an additional model 310 that is a model different from one or more step models, and sets an integration method in which the output of the step model is used as an input of the additional model 310. The integrated model 104 includes step models 303, 305, 307, and 309 connected in parallel and the additional model 310. In addition, the step models 303, 305, 307, and 309 correspond to the step model 102 of FIG. 1.

In the integrated model 104, a parameter 302 of step 1 of the processing condition 301 (for example, each value of the items “CF₄”, “CL₂”, “Ar”, and “processing time”. The same applies to parameters of other steps.) is input into the step model 303. Similarly, the parameter 304 of step 2, the parameter 306 of step 3, and the parameter 308 of step 4 are input into the step models 305, 307, and 309, respectively. The output of each step model is input into the additional model 310.

The learning unit 106 trains model parameters of the step models 303, 305, 307, and 309 and the additional model 310 such that the output of the additional model 310 is consistent with the processing result associated with the processing condition 301. For example, the model parameters are a weight for input data, which is a fitting parameter, a bias for adjusting a prediction value, and the like, in a case of a linear regression model, and is a parameter unique to a non-linear function, such as a coefficient, a cardinal, and an exponent for each term of the non-linear function, in a case of a non-linear regression model. In addition, in a case of a neural network model, the model parameter includes a learning rate, the number of epochs, the number of units in a hidden layer, and the like.

### (Another Example of Integration Method)

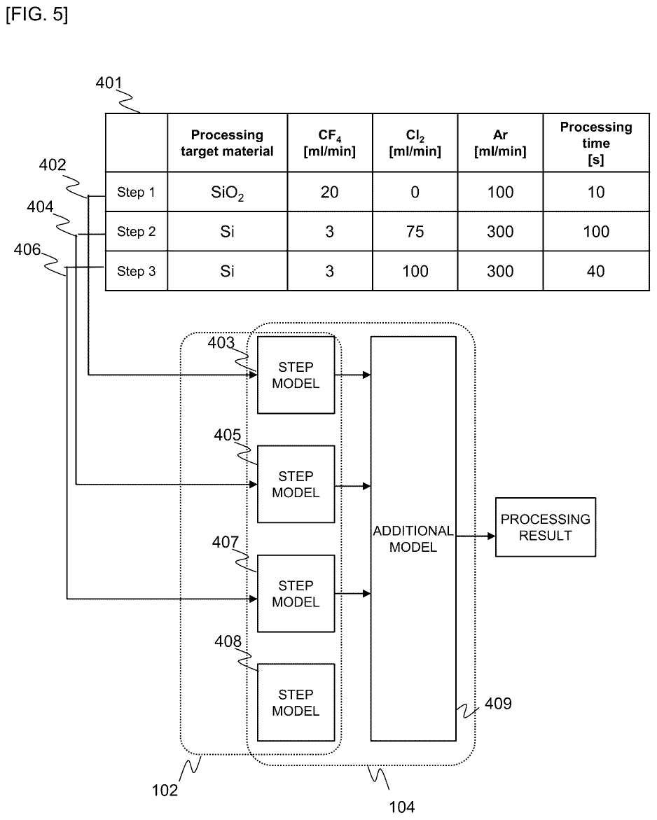

In addition, FIG. 5 illustrates a process from an input to an output when a processing condition having the number of steps, which is different from the processing condition 301, is input into the integrated model 311. FIG. 5 is a diagram illustrating an example of an integration method when the number of steps of the processing condition and the number of steps of the integrated model are different in Embodiment 1. The integrated model 104 includes step models 403, 405, and 407 and an additional model 409. In addition, the step model 102 includes step models 403, 405, 407, and 408. In addition, steps 1 to 3 of the processing condition 301 of FIG. 5 have the same values (parameters) as steps 1 to 3 of the processing condition 301 of FIG. 4.

The processing condition 401 includes three steps. In this case, the parameter 402 of step 1 of the processing condition 401 is input into the step model 403. Similarly, the parameter 404 of step 2 and the parameter 406 of step 3 are input into the step models 405 and 407, respectively. On the other hand, since the fourth step does not exist in the processing condition 401, nothing is input into the step model 408. The output of each step model is input into the additional model 409. When an input size of the additional model 409 is not variable, a dummy output, for example, 0 or the like is output from the step model 408, which is included in the input of the additional model 409.

### (Still Another Example of Integration Method)

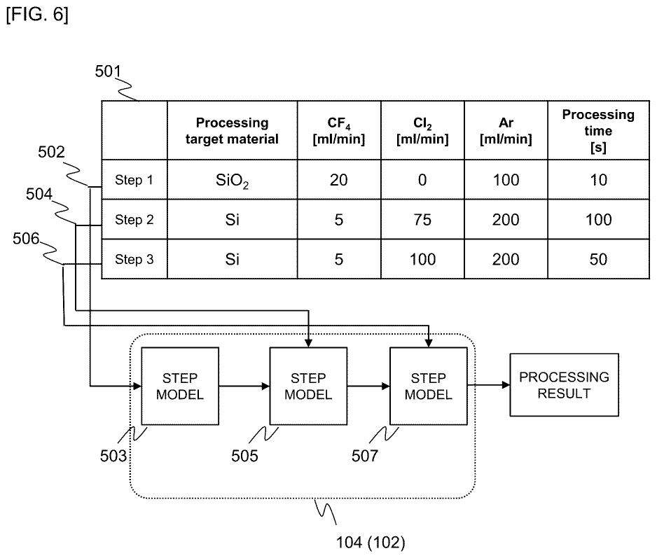

FIG. 6 illustrates still another example of the integration method in Embodiment 1. The integration method is a method of combining a step model corresponding to one step and a step model corresponding to the other step by using an output of the step model corresponding to one step as an input of the step model corresponding to the other step, and one step is a step before the other step. FIG. 6 is a diagram illustrating still another example of the integrated model in Embodiment 1. In the integration method of the step models illustrated in FIG. 6, the step models are combined with each other by using an output of a step model associated with a certain step from among one or more step models as an input of a step model associated with the next step. The integrated model 104 includes step models 503, 505, and 507 connected in series. In addition, the step model 102 includes step models 503, 505, and 507.

In the integrated model 104, the parameter 502 of step 1 of a processing condition 501 is input into the step model 503. Next, the output of the step model 503 and the parameter 504 of step 2 are input into the step model 505. Similarly, the output of the step model 505 and the parameter 506 of step 3 are input into the step model 507. The model parameters of the step models 503, 505, and 507 are trained by the learning unit 106 such that the output of the step model 507 is consistent with a processing result associated with the processing condition 501.

In Embodiment 1, the integration method setting unit 103 may not be an essential component. For example, when the integration method is determined in advance or when an integrated model generated outside the semiconductor device manufacturing system 1 already exists, the integration method setting unit 103 may not be included in the semiconductor device manufacturing system 1.

### (Flowchart of Process in Semiconductor Device Manufacturing System)

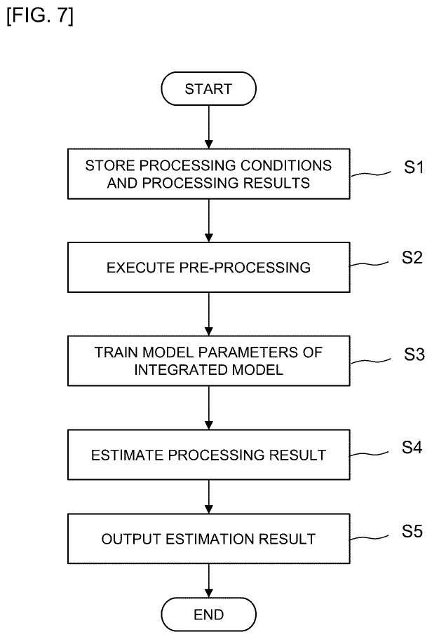

FIG. 7 is a diagram illustrating a flowchart of a process performed by the semiconductor device manufacturing system of Embodiment 1. In step S1, the semiconductor device manufacturing system 1 stores processing results and processing conditions. For example, processing conditions acquired by an experiment and processing results, which are results obtained by measuring processing targets processed based on the processing conditions, are stored in the experimental database 101.

Next, in step S2, the semiconductor device manufacturing system 1 executes pre-processing. The pre-processing unit 105 executes the pre-processing on the stored data to generate training data.

Next, in step S3, the semiconductor device manufacturing system 1 trains the model parameters of the integrated model. The integrated model 104 is a model that is associated with each step of the processing conditions stored in step S1 and integrates one or more step models included in the step model 102. The learning unit 106 trains the model parameters of the integrated model using the training data generated in step S2.

Next, in step S4, the semiconductor device manufacturing system 1 estimates the processing result. The estimation unit 107 estimates a processing result when the processing target is processed based on a desired processing condition of the user by using the trained integrated model 104 trained in step S3.

Next, in step S5, the semiconductor device manufacturing system 1 outputs the estimation result. The estimation result output unit 108 outputs the estimation result in step S4 as a processing result associated with the desired processing condition.

### (Action and Effect)

In the present disclosure, a plurality of processing conditions having different numbers of steps or different step structures is used as training data to train the model. In addition, the integrated model used for estimating the processing result can be set according to the input processing condition. Therefore, even if the desired processing condition of the user has the number of steps or step structure that is different from the processing condition used as the training data, the parameter can be input into the integrated model corresponding to each step included in the desired processing condition of the user, and the processing result can be estimated.

### Embodiment 2

### (Configuration and Process of System)

A second embodiment of a semiconductor device manufacturing system that estimates a processing result in a plasma etching process will be described. An application further executes a label assignment step of assigning a label to the step, and each of step models corresponding to a step to which the same label is assigned is the same step model. The semiconductor device manufacturing system of Embodiment 2 is different from the semiconductor device manufacturing system of Embodiment 1 in that the semiconductor device manufacturing system of Embodiment 2 includes a label assignment unit 602 that assigns a label to each step of a second processing condition (label assignment step), and the same step model is associated with the step to which the same label is assigned from among the respective steps of the second processing condition. In Embodiment 2, the semiconductor device manufacturing system, in which learning is easily performed due to a reduction in the number of step models by assigning a label according to information about a processing target material or the like in a step of a processing condition and sharing the same step model in the step of the same label, will be described. In the following description, the same or equivalent components as those in Embodiment 1 described above are denoted by the same reference numerals, and the description thereof may be simplified or omitted.

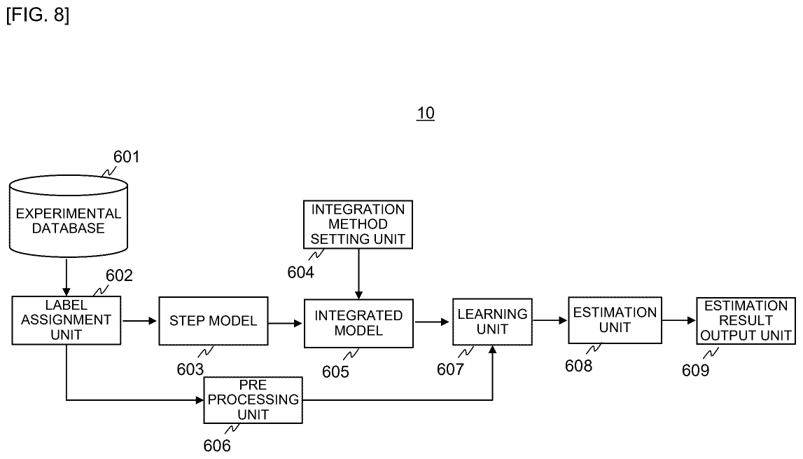

FIG. 8 is a block diagram illustrating an example of a configuration of a semiconductor device manufacturing system 10 in Embodiment 2. Specifically, the semiconductor device manufacturing system 10 in Embodiment 2 includes an experimental database 601, a label assignment unit 602, a step model 603, an integration method setting unit 604, an integrated model 605, a pre-processing unit 606, a learning unit 607, an estimation unit 608, and an estimation result output unit 609. Here, the experimental database 601, the step model 603, the integration method setting unit 604, the integrated model 605, the pre-processing unit 606, the learning unit 607, the estimation unit 608, and the estimation result output unit 609 correspond to the experimental database 101, the step model 102, the integration method setting unit 103, the integrated model 104, the pre-processing unit 105, the learning unit 106, the estimation unit 107, and the estimation result output unit 108 in the semiconductor device manufacturing system 1 of FIG. 1, respectively.

The label assignment unit 602 assigns a label for each step of the processing condition stored in the experimental database 601. The pre-processing unit 606 executes pre-processing on each step of the processing condition, and the processing content of the pre-processing is defined for each label assigned to the step.

### (Label)

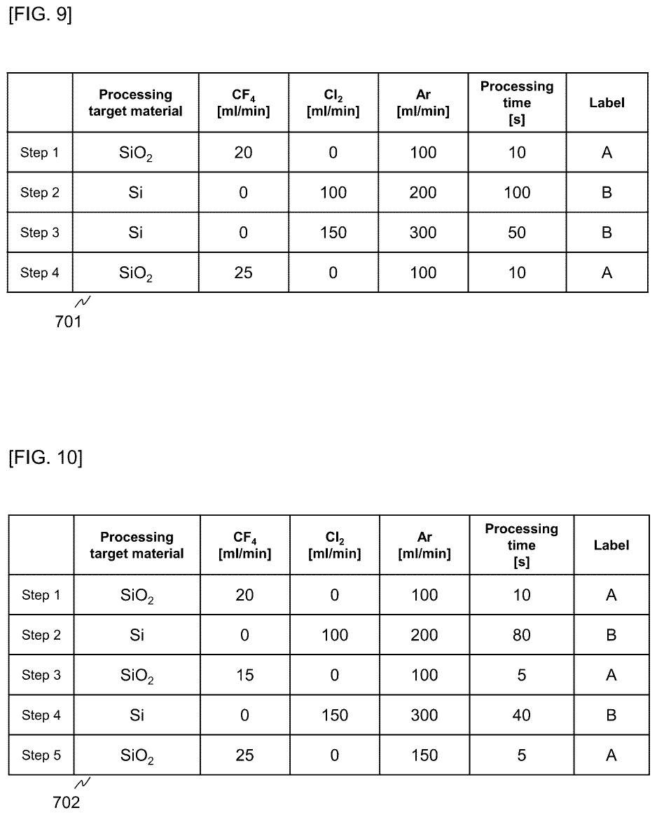

A label is assigned to the step based on the information about the processing target material in the step. FIG. 9 is a diagram illustrating an example of processing conditions in Embodiment 2. A processing condition 701 is a processing condition stored in the experimental database 601, and in Embodiment 2, unlike Embodiment 1, two types of labels A or B according to the processing target material are assigned by the label assignment unit 602. In the processing condition 701, the processing target material in both steps 1 and 4 is SiO₂, and A is assigned as a label. In addition, the processing target material in both steps 2 and 3 is Si, and B is assigned as a label. As will be described later, the step to which the same label is assigned shares the same step model (the same step model is associated).

FIG. 10 is a diagram illustrating another example of the processing conditions in Embodiment 2. In the processing condition 702, the processing condition in all steps 1, 3, and 5 is SiO₂, and A is assigned as a label. The processing target material in both steps 2 and 4 is Si, and B is assigned as a label.

The method of assigning a label does not necessarily have to correspond to the processing target material, and for example, three types of labels may be assigned according to whether the step is an etching step, a deposition step, or another step. In that case, the model estimation accuracy is expected to be improved because the information about the processing target material described in the processing conditions 701 and 702 is included in the input into the step model. This is because the information about the processing target material is included in the input of the step model, so that the step model can reflect the fact that a response of the processing result is different even when the processing target material is different from the step to which the same label is assigned. Examples of the method of including information about the processing target material in an input value of the step model includes a method of replacing the name of the processing target material with numerical value sequence data of 0 or 1 by a one-hot-encoding method and including the numerical value sequence data in an input parameter. In addition, the same step model may be shared in all steps, and the label may be converted into numerical data using a one-hot-encoding method and used as an input, so that the step model may be switched by the label associated with the step.

### (Pre-Processing Based on Label)

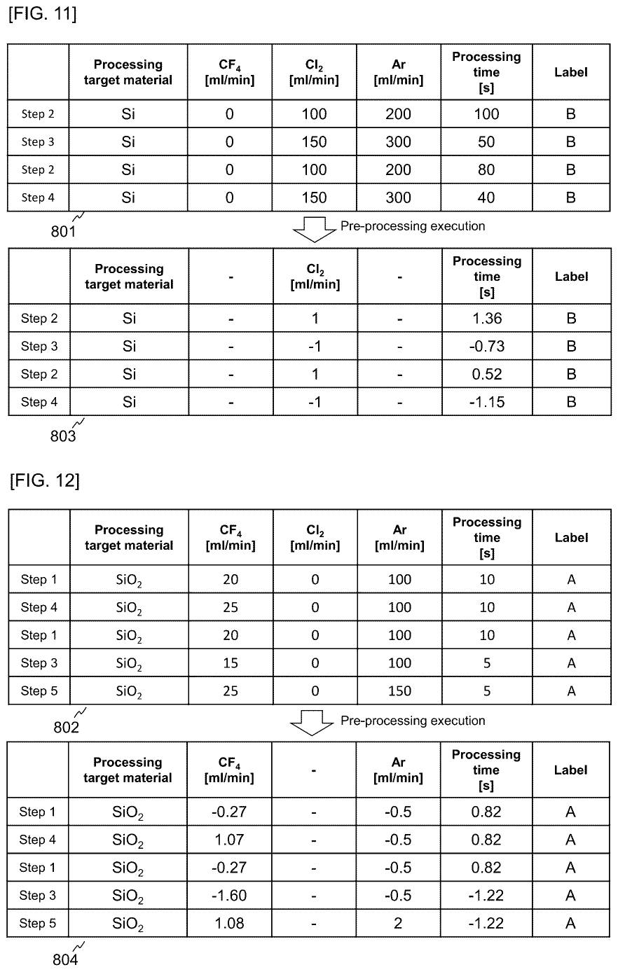

An example of the pre-processing in the pre-processing unit 606 will be described with reference to FIG. 11. FIG. 11 is a diagram illustrating an example of pre-processing of the processing conditions in Embodiment 2. Table 801 is a table in which steps of labels A and labels B in the processing condition 701 of FIG. 9 and the processing condition 702 of FIG. 10 are aggregated. Specifically, Table 801 includes steps 2 and 3 of the processing condition 701 and steps 2 and 4 of the processing condition 702.

In the pre-processing in Embodiment 2, a parameter selection and/or omission process and a parameter scaling process of the processing condition are executed. In the parameter selection and/or omission process, parameters that are unnecessary for training the regression model are deleted. Specifically, regarding CF₄, a value in each step of the processing condition 701 is 0, and a value in each step of the processing condition 702 is also 0. As a result, as in CF₄ of Table 801, the parameter that has an invariant value does not contribute to the training of the regression model, and thus is deleted from processing condition data. In addition, when there is a perfect correlation between a plurality of parameters, one parameter is left, and other left parameters are deleted. For example, in Table 801, since there is a perfect correlation of 1:2 between Cl₂ and Ar, only the parameter of Cl₂ is left and the parameter of Ar is deleted.

Next, the parameter scaling process is executed. In the scaling process, standardization is performed such that an average of the parameter values of each item is 0 and variance is 1.

Table 803 shows results of applying two pre-processing described above to Table 801.

In addition, FIG. 12 is a diagram illustrating another example of the pre-processing of the processing conditions in Embodiment 2. Table 802 includes steps 1 and 4 of the processing condition 701 and steps 1, 3, and 5 of the processing condition 702.

In the parameter selection and/or omission process of the processing condition, since the value of Cl₂ is 0 in the steps of both the processing condition 701 and the processing condition 702, the parameter of Cl₂ is deleted. Next, the parameter scaling process is executed. Table 804 shows the results of applying the parameter selection and/or omission process and the parameter scaling process to Table 802.

In the learning unit 607, data obtained by performing the processes is used as training data. Although the pre-processing for the processing conditions 801 and 802 has been described, in practice, the same processing is executed for all the data stored in the experimental database 101.

### (Example of Integration Method)

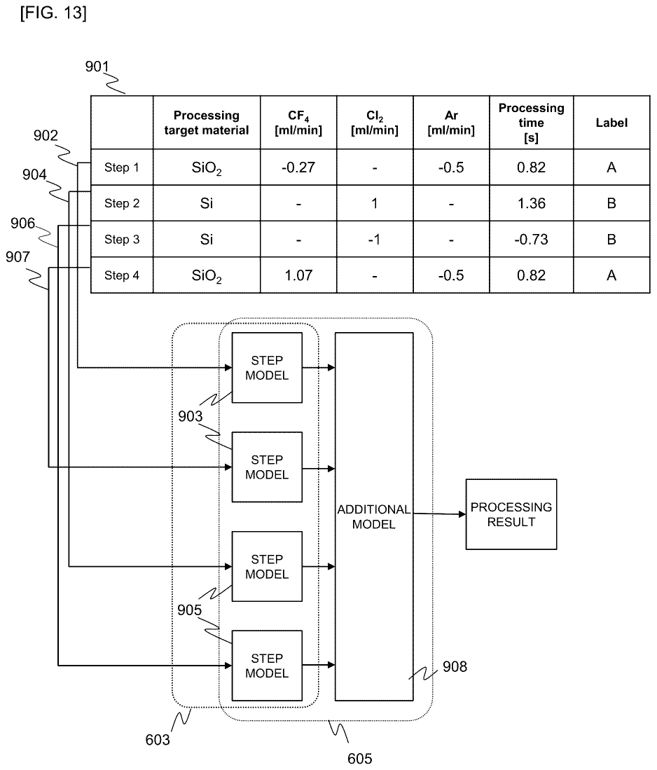

The integration method setting unit 604 sets the integration method when step models 603 are integrated to generate one integrated model. FIG. 13 illustrates an example of the integration method in Embodiment 2. FIG. 13 is a diagram illustrating an example of an integrated model 605 in Embodiment 2. The integrated model 605 includes two step models 903, two step models 905, and an additional model 908, and outputs of two step models 903 and two step models 905 arranged in parallel are input into the additional model 908. In addition, the step models 903 and 905 correspond to the step model 603 of FIG. 8.

Specifically, the step model 903 is a model associated with the label A, and the step model 905 is a model associated with the label B. The model parameters of two step models 903 are common. Similarly, the model parameters of two step models 905 are common. Since the labels of steps 1 and 4 of a processing condition 901 are A, the parameters 902 and 907 are input into the step model 903. In addition, since the labels of steps 2 and 3 of the processing condition 901 are B, the parameters 904 and 906 are input into the step model 905. The outputs of the step models 903 and 905 are input into the additional model 908. The model parameters of the step models 903 and 905 and the additional model 908 are trained by the learning unit 607 such that the output of the additional model 908 is consistent with a processing result associated with the processing condition 901. The step model 903 corresponding to two steps is a model using the common model parameters even after training. The same applies to the step model 905.

### (Another Example of Integration Method)

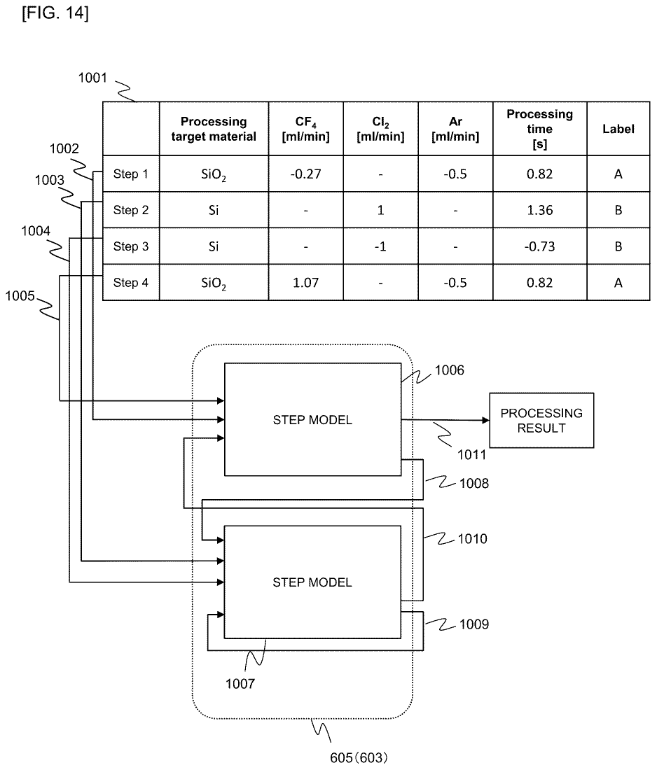

FIG. 14 illustrates another example of the integration method in Embodiment 2. FIG. 14 is a diagram illustrating another example of the integrated model in Embodiment 2. The integrated model 605 includes a step model 1006 and a step model 1007. In addition, the step model 603 includes the step models 1006 and 1007.

The step model 1006 is a model associated with the label A, and the step model 1007 is a model associated with the label B. The processing condition 1001 includes four steps. First, since the label of step 1 of the processing condition 1001 is A, the parameter 1002 is input into the step model 1006, and the step model 1006 outputs an output 1008.

Next, since the label of step 2 of the processing condition 1001 is B, the parameter 1003 is input into the step model 1007. At the same time, the output 1008 of the step model 1006 is also input into the step model 1007. As a result, the step model 1007 outputs an output 1009.

Next, since the label of step 3 of the processing condition 1001 is also B, the parameter 1004 is input into the step model 1007. At the same time, the output 1009 of the step model 1007 is also input into the step model 1007. As a result, the step model 1007 outputs an output 1010.

Finally, since the label of step 4 of the processing condition 1001 is A, the parameter 1005 is input into the step model 1006. At the same time, the output 1010 of the step model 1007 is also input into the step model 1006. As a result, the step model 1006 outputs an output 1011. The model parameters of the step models 1006 and 1007 are trained by the learning unit 607 such that the output 1011 is consistent with a processing result associated with the processing condition 1001. As described above, examples of the method of using the output of a certain model again as an input of the model include a recurrent neural network, and the like.

### (Flowchart of Process in Semiconductor Device Manufacturing System)

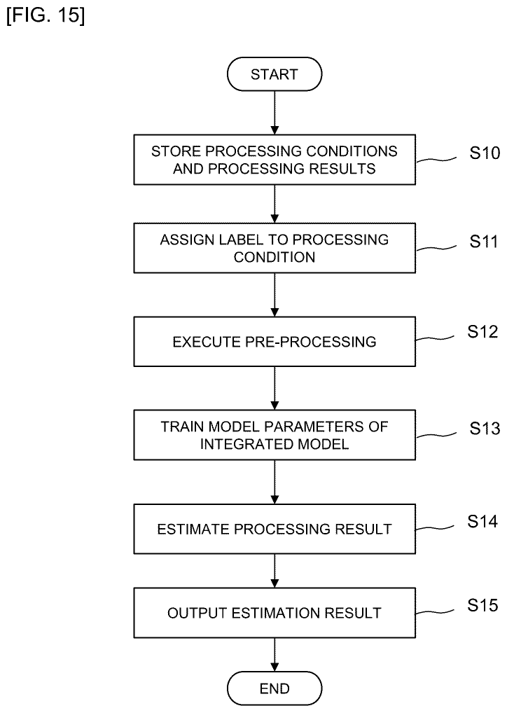

FIG. 15 is a diagram illustrating a flowchart of a process performed by the semiconductor device manufacturing system of Embodiment 2. In the flowchart of FIG. 15, step S11 is a process newly added in Embodiment 2. Steps S10 and S12 to S15 correspond to steps S1 to S5 in the flowchart of Embodiment 1 illustrated in FIG. 7, respectively.

First, in step S10, the semiconductor device manufacturing system 10 stores processing conditions and processing results. The processing conditions and the processing results are stored in the experimental database 601.

Next, in step S11, the semiconductor device manufacturing system 10 assigns a label to the processing condition. The label assignment unit 602 assigns a label to each step of the processing condition. The processing condition to which the label is assigned is stored in the experimental database 601. The user can also set the label through the label assignment unit 602.

Next, in step S12, the semiconductor device manufacturing system 10 executes pre-processing. The pre-processing unit 105 executes the pre-processing on the stored data to generate training data. As the pre-processing, for example, a parameter acquisition selection process and a parameter scaling process are performed.

Next, in step S13, the semiconductor device manufacturing system 10 trains the model parameters of the integrated model. In the integrated model 605, the parameters of the step to which the common label is assigned are input into the common step model.

Next, in step S14, the semiconductor device manufacturing system 10 estimates the processing result. Next, in step S15, the semiconductor device manufacturing system 10 outputs the estimation result.

### (Action and Effect)

In Embodiment 2, a label is assigned to each step of the processing condition, and a step model corresponding to the label is created. Since the step to which the common label is assigned shares one step model as compared with a case where the step model is created for each step as in Embodiment 1, the number of models included in the integrated model can be reduced. Therefore, it is possible to easily perform training of the model parameters of the integrated model, in other words, the model parameters of the step model included in the integrated model.

### Embodiment 3

### (Configuration and Process of System)

A third embodiment of a semiconductor device manufacturing system that estimates a processing result in a plasma etching process will be described. The model parameter of the step model in a target processing step of the step is trained by referencing the model parameter of the reference step model, and the reference step model is the step model trained in a processing step different from the target processing step of the step. The model parameter of the step model is trained by referencing the model parameter of the reference step model to which a label that is the same as the label of the step is assigned, and the reference step model is the step model trained in a processing step different from the target processing step. The semiconductor device manufacturing system of Embodiment 3 is different from Embodiments 1 and 2 in that the semiconductor device manufacturing system of Embodiment 3 further has a reference step model database that stores a reference step model, which is a trained model in a reference step that is a step different from the target step corresponding to the second processing condition, and model parameters of the step model in the target step are determined by referencing the model parameters of the reference step model. In Embodiment 3, the semiconductor device manufacturing system that efficiently trains the step model of the target step by referencing the model parameters of the step model trained in a step similar to the target step will be described. In the following description, the same or equivalent components as those in Embodiments 1 and 2 described above are denoted by the same reference numerals, and the description thereof may be simplified or omitted.

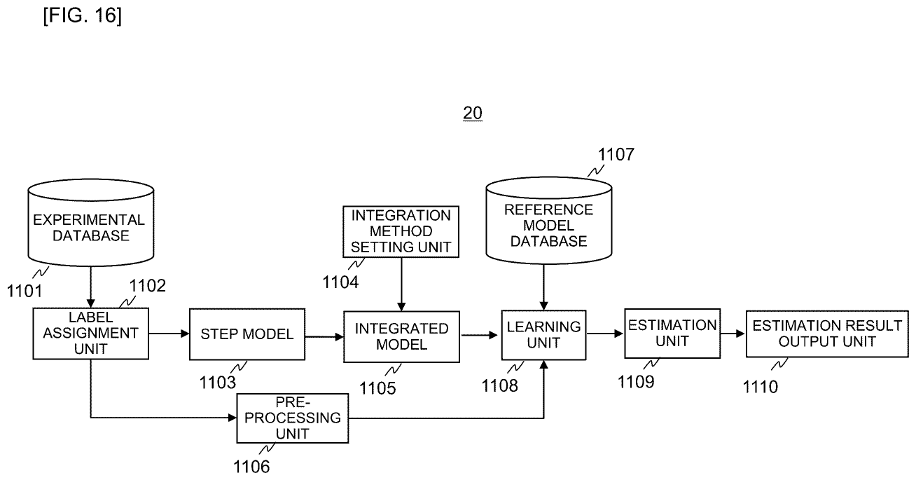

FIG. 16 is a block diagram illustrating an example of a configuration of a semiconductor device manufacturing system 20 of Embodiment 3. The semiconductor device manufacturing system 20 in Embodiment 3 includes an experimental database 1101, a label assignment unit 1102, a step model 1103, an integration method setting unit 1104, an integrated model 1105, a pre-processing unit 1106, a reference model database 1107, a learning unit 1108, an estimation unit 1109, and an estimation result output unit 1110. Here, the experimental database 1101, the label assignment unit 1102, the step model 1103, the integration method setting unit 1104, the integrated model 1105, the pre-processing unit 1106, the learning unit 1108, the estimation unit 1109, and the estimation result output unit 1110 correspond to the experimental database 601, the label assignment unit 602, the step model 603, the integration method setting unit 604, the integrated model 605, the pre-processing unit 606, the learning unit 607, the estimation unit 608, and the estimation result output unit 609 in the semiconductor device manufacturing system 10 of FIG. 8, respectively.

The reference model database 1107 stores a step model or additional model trained using training data in other processing steps different from processing conditions stored in the experimental database 1101. The step model and the additional model stored in the reference model database 1107 are referred to as a trained reference step model and a trained reference additional model by distinguishing the step model and the additional model from a step model included in the step model 1103 and an additional model included in the integrated model 1105, respectively. In addition, as will be described later, the trained reference step model and the trained reference additional model are associated with labels assigned to the training data used for the training.

### (Target Step and Reference Step)

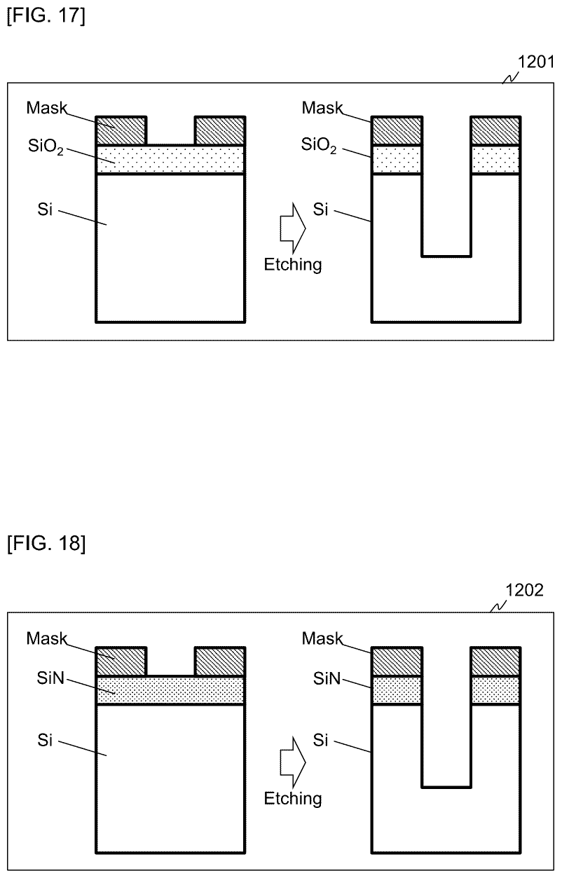

The target step and the reference step will be described with reference to FIGS. 17 and 18. FIG. 17 is a diagram illustrating an example of the target step in Embodiment 3. In Embodiment 3, a target step 1201 of FIG. 17 serves as trench etching having a structure in which SiO₂ is stacked on Si. The etching is performed according to a shape of a mask disposed on SiO₂ to remove SiO₂ and Si, thereby forming a trench.

On the other hand, FIG. 18 is a diagram illustrating an example of the reference step in Embodiment 3. In a reference step 1202 of FIG. 18, etching is performed according to the shape of the mask disposed on SiN, which is trench etching having a structure in which SiN is stacked on Si to remove SiN and Si, thereby forming a trench.

The reference model database 1107 stores a step model or additional model trained in the reference step 1202 of FIG. 18. There is a difference in whether a material on Si is SiO₂ or SiN in the target step 1201 and the reference step 1202, but the etching process of Si that is below the material is similar.

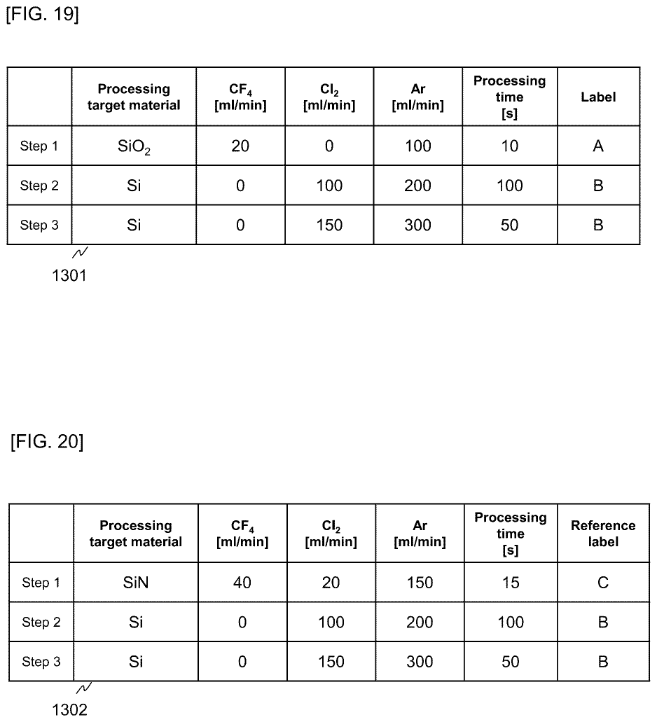

The processing conditions of the target step 1201 and the reference step 1202 will be described with reference to FIGS. 19 and 20. FIG. 19 is a diagram illustrating an example of processing conditions of the target step 1201 in Embodiment 3. A processing condition 1301 of FIG. 19 is a processing condition corresponding to the target step 1201 of FIG. 17, and is a processing condition stored in the experimental database 1101. In the processing condition 1301, step 1 is assigned with a label A, and steps 2 and 3 are assigned with a label B. In the etching process, a process of removing SiO₂ on Si corresponds to step 1, and a process of removing Si after removing SiO₂ corresponds to steps 2 and 3.

On the other hand, FIG. 20 is a diagram illustrating an example of processing conditions of the reference step 1202 in Embodiment 3. A processing condition 1302 of FIG. 20 is an example of a processing condition used for training the reference step model stored in the reference model database 1107. In addition, in the processing condition 1302, step 1 is assigned with a reference label C, and steps 2 and 3 are assigned with a reference label B. In the etching process, a process of removing SiN on Si corresponds to step 1, and a process of removing Si after removing SiN corresponds to steps 2 and 3. In order to distinguish the label of the target step, the label in the reference step is referred to as a reference label for the sake of convenience. In any of the target step and the reference step, the label is assigned according to a processing target material.

All of the steps 2 and 3 to which the label B is assigned in the processing condition 1301 and steps 2 and 3 to which the label B is assigned in the processing condition 1302 are processing that corresponds to trench etching of Si, and it is considered that the etching proceeds through a similar mechanism in the plasma etching process based on the steps. Therefore, in Embodiment 3, the trained reference step model associated with the label B stored in the reference model database 1107 is utilized. Specifically, the learning unit 1108 determines a model parameter of the step model 1103 associated with the label B in the target step 1201 with reference to the model parameter of the trained reference step model associated with the label B. Accordingly, when the reference step model is trained with a large amount of training data, even if the number of training data in the target step 1201 is small and it is difficult to train the step model 1103, it is expected that the step model 1103 can be trained with high accuracy by referencing the model parameters of the trained reference step model.

### (Training of Model Parameter Utilizing Reference Step Model)

As an example of the method of utilizing the reference step model, when the model parameter of the step model is trained by the learning unit 1108, it is considered that a change from the model parameter of the reference step model is restricted. As for a penalty function defined for the integrated model, which includes a term indicating the degree of deviation between the model parameter of the step model and the model parameter of the reference step model, and model parameters of the integrated model that reduce a value of the penalty function are searched for.

Specifically, as the penalty function, for example, a loss function is defined such that a penalty is imposed as it deviates from the value of the model parameter of the reference step model. The learning unit 1108 searches for model parameters of the step model 1103 of the target step such that the loss function is minimized. Here, the form of the loss function can be represented by, for example, a sum of a term representing a difference between the output of the integrated model 1105 and the processing result stored in the experimental database 1101, and the penalty term p indicating the penalty, and the like. As a result, the deviation of the model parameter of the reference step model can be restricted.

Equation (1) shows an example of the loss function. In Equation (1), a term indicating an output of the integrated model 1105 is f(xᵢ|w) (xᵢ indicates a parameter of an i-th (i is a positive integer) processing condition, and w indicates a model parameter). In addition, the term indicating the processing result stored in the experimental database 1101 is yᵢ (yᵢ indicates a processing result associated with the i-th processing condition). The penalty term is p(w). In Equation (1), the first term is shown as a squared sum error.

$$\begin{matrix}[ Equation 1 ] & \\ L ( ω \vert X ) = {\sum }_{i = 1}^{n} {‖ f ( {x}_{i} , w ) - {y}_{i} ‖}^{2} + p ( w ) & ( 1 )\end{matrix}$$

w: Model parameter
N: Number of training data
xᵢ: Parameter of i-th processing condition
yᵢ: Processing result associated with i-th processing condition

Another example of the method of utilizing the reference step model includes transfer learning. Here, when both the step model of the target step and the step model of the reference step are assumed to be neural network models, and a method of utilizing the reference step model by transfer learning will be described. The step model is a neural network, the model parameters of the integrated model are trained by an error backpropagation method, and when step model references the model parameter of the reference step model, a value of the model parameter of the reference step model is set as an initial value of the model parameter of the step model, and a value of a learning rate obtained by the error backpropagation method in the step model or a frequency of updating the model parameter in the step model is set to be lower than that when the step model does not reference the model parameter of the reference step model. Specifically, in the transfer learning, the learning unit 1108 sets the model parameter of the reference step model as an initial value of the model parameter of the step model 1103 of the target step, and then trains the model parameter of the step model 1103 using the training data of the target step by the error backpropagation method. In the step model trained by the transfer learning from the reference step model, the deviation from the model parameter of the reference step model can be restricted by setting the value of the learning rate or the frequency of updating the model parameter in the error backpropagation to be lower than that in other step models.

When the label is assigned according to the processing target material as in Embodiment 3, a reference step model to which the same label as the step model of the target step is assigned can be referenced. For example, the learning unit 1108 can determine the model parameter of the step model in the target step by referencing the model parameter of the reference step model (hereinafter, also referred to as a “reference model parameter”) associated with the same label as the label that is assigned to the step included in the processing condition corresponding to the target step. Thus, the search accuracy of the model parameter is expected to be further improved. This is because, even in different processing steps, when the processing target material is the same, the processing mechanism is similar, and therefore the model parameter of the step model for describing the processing is also likely to be similar.

Although a case where the model parameter of the step model of the integrated model is trained has been described, the present disclosure is not limited to the case. When the integrated model includes the step model and the additional model, it is possible to reference the model parameter of the reference additional model even when the model parameter of the additional model is trained.

### (Flowchart of Process in Semiconductor Device Manufacturing System)

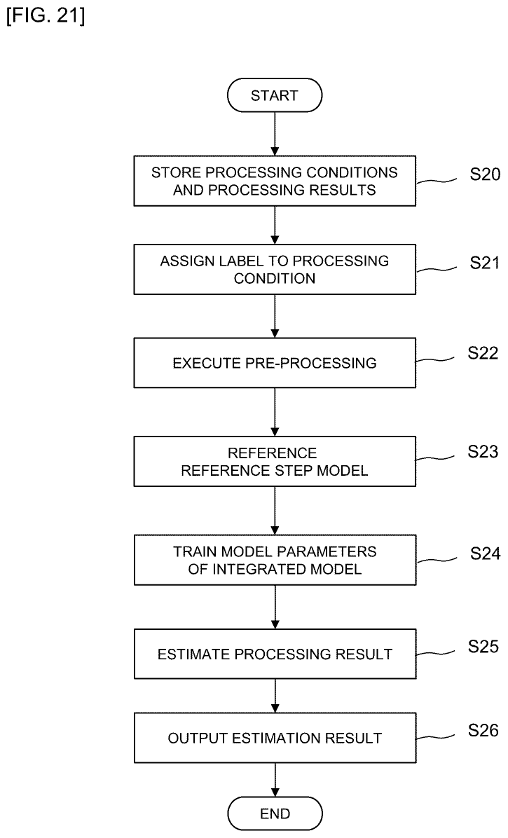

FIG. 21 is a diagram illustrating a flowchart of processing performed by the semiconductor device manufacturing system of Embodiment 3. Step S23 is a process newly added in Embodiment 3 as compared with the flowchart of Embodiment 2 illustrated in FIG. 15. Steps S20 to S22 and steps S24 to S26 correspond to steps S10 to S15 in the flowchart of Embodiment 2 illustrated in FIG. 15, respectively.

First, in step S20, the semiconductor device manufacturing system 20 stores processing conditions and processing results. The processing conditions and the processing results are stored in the experimental database 1101.

Next, in step S21, the semiconductor device manufacturing system 20 assigns a label to the processing condition. The label assignment unit 1102 assigns a label to each step of the processing condition. The processing condition to which the label is assigned is stored in the experimental database 1101.

Next, in step S22, the semiconductor device manufacturing system 20 executes pre-processing. The pre-processing unit 1106 executes the pre-processing on the stored data to generate training data. As the pre-processing, for example, a parameter acquisition selection process and a parameter scaling process are performed.

Next, in step 23, the semiconductor device manufacturing system 20 references the reference step model. The learning unit 1108 references the reference model database and searches for the trained reference step model and the trained reference additional model when the model parameters of the integrated model are trained. The learning unit 1108 determines whether or not the step included in the target step and the step included in the reference step are similar to each other, and selects a reference step model or reference additional model trained by using the reference step similar to the target step. The determination of whether or not the reference step is similar to the target step can be performed, for example, based on the label assigned to the step. In addition, the determination of whether or not the reference step is similar to the target step may be performed based on the processing target material, the parameter value, or the like, which is defined in the step. For example, it is also possible to select a model that is referenced by the user through the learning unit 1108.

Next, in step S24, the semiconductor device manufacturing system 20 trains the model parameters of the integrated model. Subsequently, the semiconductor device manufacturing system 20 estimates the processing result in step S25, and outputs the estimation result in step S26.

### (GUI)

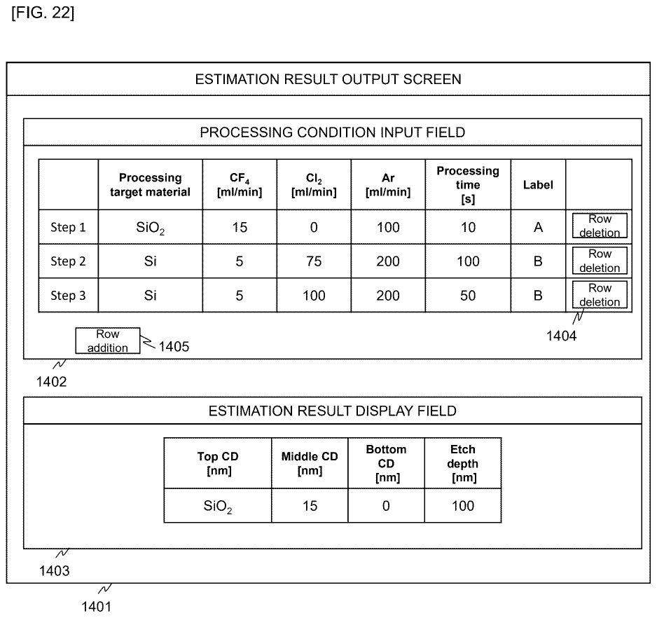

An example of a graphical user interface (GUI) of a semiconductor device manufacturing system 30 in Embodiment 3 will be described with reference to FIGS. 22 to 27. FIG. 22 is a diagram illustrating an example of a GUI for presenting an estimation result to a user in the estimation result output unit 1110. In an estimation result output screen 1401, a processing condition input field 1402 into which a desired processing condition can be input and an estimation result display field 1403 in which an estimation result of a processing result for the input processing condition is displayed are shown. A button 1404 for deleting a row and a button 1405 for adding a row are disposed in the processing condition input field 1402.

The user operates the processing condition input field 1402 to create a desired processing condition. The user inputs a processing target material, a flow rate of a gas, a processing condition, and a label for each step, and creates the processing condition including a plurality of steps. The estimation result display field 1403 includes items of “Top CD”, “Middle CD”, “Bottom CD”, and “Etch Depth”. Other items may be included as the estimation results.

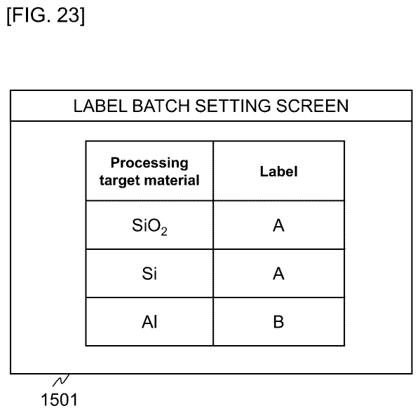

FIG. 23 is a diagram illustrating an example of a GUI for the user to assign a label by the label assignment unit 1102. A label batch setting screen 1501 shows a case where a label is collectively set for each processing target material. The label assignment unit 1102 assigns a label to each step of the processing condition stored in the experimental database 1101 according to the label set on the label batch setting screen 1501.

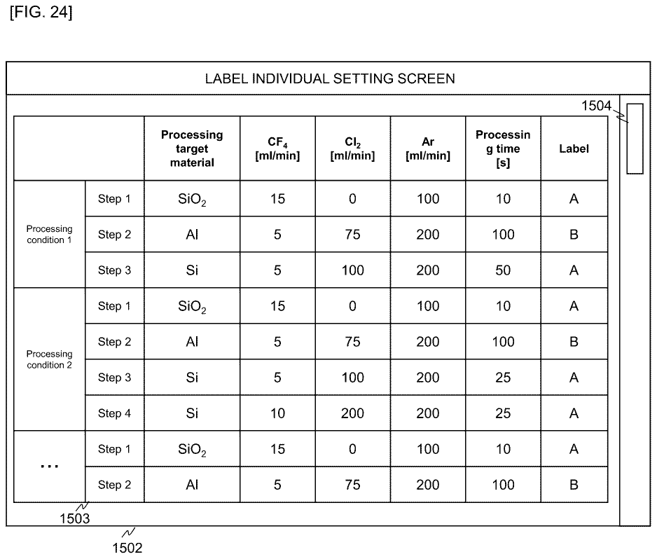

In addition, FIG. 24 is a diagram illustrating another example of the GUI for the user to assign a label by the label assignment unit 1102. In the label individual setting screen 1502, the label can be individually edited for each step of the processing condition. A label individual setting screen 1502 displays a list 1503 of processing conditions stored in the experimental database 1101 and has a scroll bar 1504. The user can individually assign a label for each step by editing a column of the label of the list 1503 of the processing conditions.

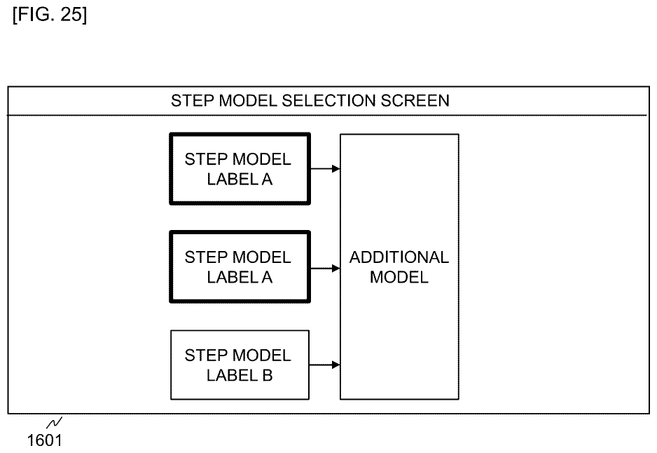

In addition, FIG. 25 is a diagram illustrating an example of a GUI for searching for and selecting a reference step model to be referenced from the reference model database 1107. In a step model selection screen 1601, the user selects the step model of the target processing step that is to be trained by utilizing the reference step model. The selected step model is displayed, for example, highlighted with a bold line. In the example illustrated in FIG. 25, the step model to which the label A is assigned is selected.

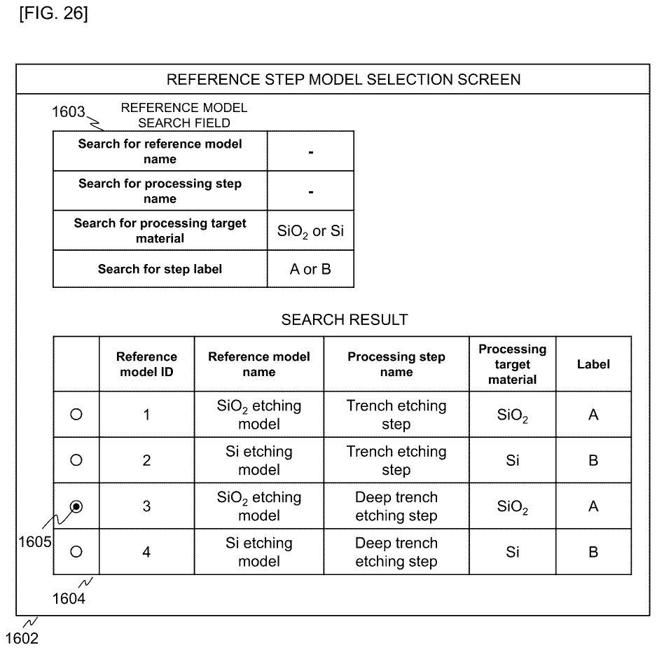

In addition, FIG. 26 is a diagram illustrating another example of the GUI for searching and selecting the reference step model to be referred from the reference model database 1107. A reference step model selection screen 1602 has a reference model search field 1603 and a search result display field 1604, and the step model selected on the step model selection screen 1601 of FIG. 25 can be selected as the reference step model to be referenced. In a reference model search field 1603, the user inputs a search equation related to various attributes of the reference step model, for example, a processing target material, a label, or the like. In a search result display field 1604, a list of reference step models, which is consistent with a search equation that is input into the reference model search field 1603, is displayed. The search result display field 1604 includes a radio button 1605 for the user to select a reference step model that is to be utilized for training the step model. In the example illustrated in FIG. 26, a SiO₂ etching model of a reference model ID3 of FIG. 26 is used for the training of the step model of the label A of FIG. 25.

### (Action and Effect)

Even when it is difficult to secure the accuracy of training the model parameter because there is little training data due to a situation in which the user does not sufficiently acquire experimental data, it is possible to improve the estimation accuracy by utilizing the trained reference models (step model and additional model) of similar steps. In addition, since it is possible to reference the step model associated with the step of a certain processing condition and to utilize the step model for estimating the processing result of another target step, the reusability of the model is improved.

### (Search System)

The semiconductor device manufacturing system according to the present disclosure can also be applied to a search system. The search system is a system for searching a setting value set in a semiconductor device manufacturing apparatus, which processes a processing target into a predetermined processed shape, in order to process the processing target into a target processed shape with respect to the semiconductor device manufacturing apparatus. For example, when the semiconductor device manufacturing apparatus is a plasma etching apparatus, the search system can search for an etching recipe of the plasma etching apparatus so as to etch a semiconductor wafer, which is a processing target, into a desired shape.

### (Hardware Configuration Example)

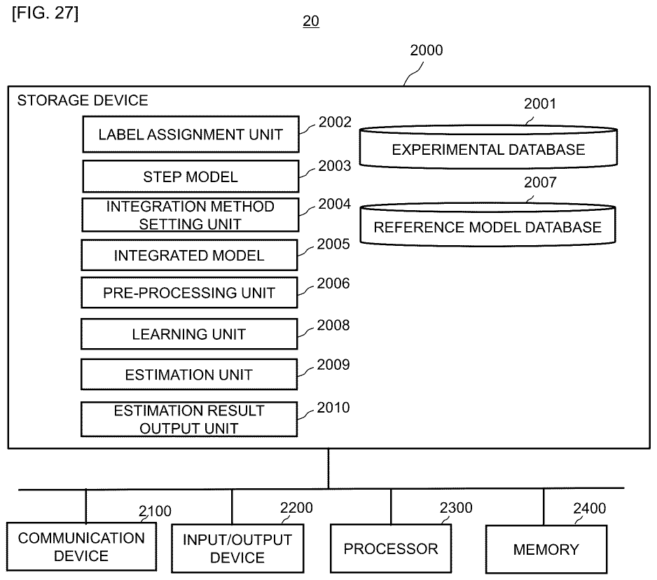

The semiconductor device manufacturing system according to the present disclosure can also be realized by hardware. FIG. 27 is a diagram illustrating an example of a hardware configuration of the semiconductor device manufacturing system 20 of Embodiment 3. The semiconductor device manufacturing system 20 includes a storage device 2000, a communication device 2100, an input/output device 2200, a processor 2300, and a memory 2400.

The storage device 2000 and the memory 2400 have a software program and/or a set of instructions executed by the processor 2300. The processor 2300 executes various software programs and/or instruction sets stored in the storage device 2000 and the memory 2400 to execute various functions for the semiconductor device manufacturing system 20 and to process data. The storage device 2000 and the memory 2400 include a non-volatile storage device such as a random access memory (RAM), a magnetic disk storage device, a flash memory device, or another non-volatile solid state memory device. Although a case where one storage device 2000, one processor 2300, and one memory 2400 are included is shown, two or more storage devices 2000, two or more processors 2300, and two or more memories 2400 may be included. In addition, the storage device 2000 and the memory 2400 may be separate devices or a single device. The memory 2400 stores, for example, a part of an operating system (OS).

The communication device 2100 is an interface for the semiconductor device manufacturing system 20 to communicate information with an external device. Examples of the external device include a semiconductor device manufacturing apparatus, a measuring apparatus for a semiconductor wafer, which is a processing target, database that stores information about processing conditions and processing results, and the like.

An input/output device 2200 is a device used when the user inputs and outputs information into and from the semiconductor device manufacturing system 20. As the input/output device 2200, for example, an output device such as a display or an input device such as a keyboard or a mouse can be applied. In addition, a device having both an input function and an output function, such as a touch panel, may be used.

The storage device 2000 stores a software program and/or an instruction set for executing the function of the semiconductor device manufacturing system 20 and data used for executing the function. The experimental database 2001 and the reference model database 2007 correspond to the experimental database 1101 and the reference model database 1107 of FIG. 16, respectively.

When the label assignment unit 2002 is executed by the processor 2300, the processor 2300 functions as the label assignment unit 1102 of FIG. 16. Similarly, the step model 2003, the combination method setting unit 2004, the integrated model 2005, the pre-processing unit 2006, the learning unit 2008, the estimation unit 2009, and the estimation result output unit 2010 are programs and/or instruction sets corresponding to the step model 1103, the integration method setting unit 1104, the integrated model 1105, the pre-processing unit 1106, the learning unit 1108, the estimation unit 1109, and the estimation result output unit 1110 of FIG. 16, respectively.

Although the hardware configuration of the semiconductor device manufacturing system 20 of Embodiment 3 has been described, the same hardware configuration can be applied to the semiconductor device manufacturing systems of Embodiments 1 and 2.

Hereinabove, the embodiments of the present invention have been described, but the present invention is not limited to the above-described embodiments, and various changes are able to be made without departing from the scope of the present invention.

Aspects that can constitute the content of the present invention will be described later, but the present invention is not limited thereto.

### (Aspect 1)

A semiconductor device manufacturing system including: a platform on which an application is implemented, the application using processing conditions of a semiconductor manufacturing apparatus, which are configured by at least one step, as an input and outputting information indicating an estimated value of a processing result obtained by the processing conditions,
in which the application executes
a learning step of training model parameters of an integrated model, which is a model obtained by integrating a step model and at least one step model that is a model in which a parameter value defined in the step is used as an input value, by using the integrated model and training data,
an estimation step of estimating information about the processing result according to a desired processing condition using the trained integrated model, and
an output step of outputting the estimated processing result,
the integrated model outputs the information about the processing result by using a parameter value of the step corresponding to the step model as the input value, and
the information about the processing result acquired in advance includes information about the processing result obtained by two or more steps.

### (Aspect 2)

The semiconductor device manufacturing system of Aspect 1,
in which the step model includes, in an input value, information about a processing target material in the step.

### (Aspect 3)

The semiconductor device manufacturing system according to Aspect 1 or 2,
in which the application further executes a training data generation step of generating the training data by performing pre-processing on data including the information about the processing condition and the information about the processing result acquired in advance, and
the pre-processing is a selection and/or omission process of the parameter or a scaling process of the parameter value.

### (Aspect 4)

The semiconductor device manufacturing system according to any one of Aspects 1 to 3,
in which the step model is a neural network, and
the model parameter is trained by an error backpropagation method.

### (Aspect 5)

The semiconductor device manufacturing system according to any one of Aspects 1 to 4,
in which the application further executes an integration method setting and/or changing step of setting an integration method of the step model or changing the integration method of the step model.

### (Aspect 6)

The semiconductor device manufacturing system according to any one of Aspects 1 to 5,
in which the integration method is a method of combining a step model corresponding to one step and a step model corresponding to the other step by using an output of the step model corresponding to the one step as an input of the step model corresponding to the other step, and
the one step is a step before the other step.

### (Aspect 7)

The semiconductor device manufacturing system according to any one of Aspects 1 to 6,
in which an additional model that is a model different from the step model is generated by the integration method setting and/or changing step,
the integration method is an integration method in which an output of the step model is used as an input of the additional model, and
the model parameters of the integrated model are trained such that an output of the additional model is the information of the processing result.

### (Aspect 8)

The semiconductor device manufacturing system according to any one of Aspects 1 to 7,
in which the application further executes a label assignment step of assigning a label to the step, and
each of the step models corresponding to the step to which the same label is assigned is the same step model.

### (Aspect 9)

The semiconductor device manufacturing system according to any one of Aspects 1 to 8,
in which the pre-processing is executed in each of the steps, and
a processing content of the pre-processing is defined for each label.

### (Aspect 10)

The semiconductor device manufacturing system according to any one of Aspects 1 to 9,
in which the label is assigned to the step based on information about a processing target material in the step.

### (Aspect 11)

The semiconductor device manufacturing system according to any one of Aspects 1 to 10,
in which the model parameter of the step model in a target processing step of the step is trained by referencing a model parameter of a reference step model, and
the reference step model is the step model trained in a processing step different from the target processing step of the step.

### (Aspect 12)

The semiconductor device manufacturing system according to any one of Aspects 1 to 11,
in which, when the model parameter of the step model is trained, a change from the model parameter of the reference step model is restricted.

### (Aspect 13)

The semiconductor device manufacturing system according to any one of Aspects 1 to 12,
in which the model parameter of the integrated model that reduces a value of a penalty function defined for the integrated model is searched for, and
a term indicating a degree of deviation between the model parameter of the step model and the model parameter of the reference step model is included in the penalty function.

### (Aspect 14)

The semiconductor device manufacturing system according to any one of Aspects 1 to 13,
in which the step model is a neural network,
the model parameters of the integrated model are trained by an error backpropagation method, and
when the step model references the model parameter of the reference step model, a value of the model parameter of the reference step model is set as an initial value of the model parameter of the step model, and a value of a learning rate obtained by the error backpropagation method in the step model or a frequency of updating the model parameter in the step model is set to be lower than that when the step model does not reference the model parameter of the reference step model.

### (Aspect 15)

The semiconductor device manufacturing system according to any one of Aspects 1 to 14,
in which the model parameter of the step model is trained by referencing the model parameter of the reference step model to which a label that is the same as the label of the step is assigned, and
the reference step model is the step model trained in the processing step different from the target processing step.

### (Aspect 16)

A processing result estimation method for using processing conditions of a semiconductor manufacturing apparatus, which are configured by at least one step, as an input and outputting information indicating an estimated value of a processing result obtained by the processing conditions, the processing result estimation method including:
a learning step of training model parameters of an integrated model, which is a model obtained by integrating a step model and at least one step model that is a model in which a parameter value defined in the step is used as an input value, by using the integrated model and training data;
an estimation step of estimating information about the processing result according to a desired processing condition using the trained integrated model; and
an output step of outputting the estimated processing result,
in which the integrated model outputs the information about the processing result by using a parameter value of the step corresponding to the step model as the input value, and
the information about the processing result acquired in advance includes information about the processing result obtained by two or more steps.

### (Aspect 17)

A search method for searching for a desired processing condition of a semiconductor manufacturing apparatus, which is configured by at least one step, the search method including:
a learning step of training model parameters of an integrated model, which is a model obtained by integrating a step model and at least one step model that is a model in which a parameter value defined in the step is used as an input value, by using the integrated model and training data;
an estimation step of estimating information about a processing result according to the desired processing condition using the trained integrated model; and
an output step of outputting the processing condition that is obtained by using the estimated processing result as a desired processing result,
in which the integrated model outputs the information about the processing result by using a parameter value of the step corresponding to the step model as the input value, and
the information about the processing result acquired in advance includes information about the processing result obtained by two or more steps.

### (Aspect 18)

A server on which an application is implemented, the application using processing conditions of a semiconductor manufacturing apparatus, which are configured by at least one step, as an input and outputting information indicating an estimated value of a processing result obtained by the processing conditions,
in which the application executes
a learning step of training model parameters of an integrated model, which is a model obtained by integrating a step model and at least one step model that is a model in which a parameter value defined in the step is used as an input value, by using the integrated model and training data,
an estimation step of estimating information about the processing result according to a desired processing condition using the trained integrated model, and
an output step of outputting the estimated processing result,
the integrated model outputs the information about the processing result by using a parameter value of the step corresponding to the step model as the input value, and
the information about the processing result acquired in advance includes information about the processing result obtained by two or more steps.

### DESCRIPTION OF REFERENCE NUMERALS

101: experimental database
102: step model
103: integration method setting unit
104: integrated model
105: pre-processing unit
106: learning unit
107: estimation unit
108: estimation result output unit
201: processing condition
202: processing condition
301: processing condition
302: processing condition of step 1
303: step model of step 1
304: processing condition of step 2
305: step model of step 2
306: processing condition of step 3
307: step model of step 3
308: processing condition of step 4
309: step model of step 4
401: processing condition
402: processing condition of step 1
403: step model of step 1
404: processing condition of step 2
405: step model of step 2
406: processing condition of step 3
407: step model of step 3
408: step model of step 4
409: additional model
501: processing condition
502: processing condition of step 1
503: step model of step 1
504: processing condition of step 2
505: step model of step 2
506: processing condition of step 3
507: step model of step 3
601: experimental database
602: label assignment unit
603: step model
604: integration method setting unit
605: integrated model
606: pre-processing unit
607: learning unit
608: estimation unit
609: estimation result output unit
701: processing condition 1
702: processing condition 2
801: processing condition of label B
802: processing condition of label A
803: processing condition after pre-processing label B
804: processing condition after pre-processing label A
901: processing condition
902: processing condition of step 1
903: step model of label A
904: processing condition of step 2
905: step model of label B
906: processing condition of step 3
907: processing condition of step 4
908: additional model
1001: processing condition
1002: processing condition of step 1
1003: processing condition of step 2
1004: processing condition of step 3
1005: processing condition of step 4
1006: step model of label A
1007: step model of label B
1008: output of step 1
1009: output of step 2
1010: output of step 3
1011: output of step 4
1101: experimental database
1102: label assignment unit
1103: step model
1104: integration method setting unit
1105: integrated model
1106: pre-processing unit
1107: reference model database
1108: learning unit
1109: estimation unit
1110: estimation result output unit
1201: target step
1202: reference step
1301: target step processing condition
1302: reference step processing condition
1401: estimation result output screen
1402: processing condition input field
1403: estimation result display field
1404: row deletion button
1405: row addition button
1501: label batch setting screen
1502: label individual setting screen
1503: processing condition list
1504: scroll bar
1601: step model selection screen
1602: reference step model selection screen
1603: reference model search field
1604: search result display field
1605: radio button
2000: storage device
2001: experimental database
2002: label assignment unit
2003: step model
2004: combination method setting unit
2005: combination model
2006: pre-processing unit
2007: reference model database
2008: learning unit
2009: estimation unit
2010: estimation result output unit
2100: communication device
2200: input/output device
2300: processor
2400: memory

1. A semiconductor device manufacturing system comprising: a platform on which an application is implemented, the application using processing conditions of a semiconductor manufacturing apparatus, which are configured by at least one step, as an input and outputting information indicating an estimated value of a processing result obtained by the processing conditions,
wherein the application executes
a learning step of training model parameters of an integrated model, which is a model obtained by integrating a step model and at least one step model that is a model in which a parameter value defined in the step is used as an input value, by using the integrated model and training data,
an estimation step of estimating information about the processing result according to a desired processing condition using the trained integrated model, and
an output step of outputting the estimated processing result,
the integrated model outputs the information about the processing result by using a parameter value of the step corresponding to the step model as the input value, and
the information about the processing result acquired in advance includes information about the processing result obtained by two or more steps.

2. The semiconductor device manufacturing system of claim 1,
wherein the step model includes, in an input value, information about a processing target material in the step.

3. The semiconductor device manufacturing system according to claim 1,
wherein the application further executes a training data generation step of generating the training data by performing pre-processing on data including the information about the processing condition and the information about the processing result acquired in advance, and
the pre-processing is a selection and/or omission process of the parameter or a scaling process of the parameter value.

4. The semiconductor device manufacturing system according to claim 1,
wherein the step model is a neural network, and
the model parameter is trained by an error backpropagation method.

5. The semiconductor device manufacturing system according to claim 1,
wherein the application further executes an integration method setting and/or changing step of setting an integration method of the step model or changing the integration method of the step model.

6. The semiconductor device manufacturing system according to claim 5,
wherein the integration method is a method of combining a step model corresponding to one step and a step model corresponding to the other step by using an output of the step model corresponding to the one step as an input of the step model corresponding to the other step, and
the one step is a step before the other step.

7. The semiconductor device manufacturing system according to claim 5,
wherein an additional model that is a model different from the step model is generated by the integration method setting and/or changing step,
the integration method is an integration method in which an output of the step model is used as an input of the additional model, and
the model parameters of the integrated model are trained such that an output of the additional model is the information of the processing result.

8. The semiconductor device manufacturing system according to claim 1,
wherein the application further executes a label assignment step of assigning a label to the step, and
each of the step models corresponding to the step to which the same label is assigned is the same step model.

9. The semiconductor device manufacturing system according to claim 8,
wherein the pre-processing is executed in each of the steps, and
a processing content of the pre-processing is defined for each label.

10. The semiconductor device manufacturing system according to claim 8,
wherein the label is assigned to the step based on information about a processing target material in the step.

11. The semiconductor device manufacturing system according to claim 1,
wherein the model parameter of the step model in a target processing step of the step is trained by referencing a model parameter of a reference step model, and
the reference step model is the step model trained in a processing step different from the target processing step of the step.

12. The semiconductor device manufacturing system according to claim 11,
wherein, when the model parameter of the step model is trained, a change from the model parameter of the reference step model is restricted.

13. The semiconductor device manufacturing system according to claim 12,
wherein the model parameter of the integrated model that reduces a value of a penalty function defined for the integrated model is searched for, and
a term indicating a degree of deviation between the model parameter of the step model and the model parameter of the reference step model is included in the penalty function.

14. The semiconductor device manufacturing system according to claim 12,
wherein the step model is a neural network,
the model parameters of the integrated model are trained by an error backpropagation method, and
when the step model references the model parameter of the reference step model, a value of the model parameter of the reference step model is set as an initial value of the model parameter of the step model, and a value of a learning rate obtained by the error backpropagation method in the step model or a frequency of updating the model parameter in the step model is set to be lower than that when the step model does not reference the model parameter of the reference step model.

15. The semiconductor device manufacturing system according to claim 11,
wherein the model parameter of the step model is trained by referencing the model parameter of the reference step model to which a label that is the same as the label of the step is assigned, and
the reference step model is the step model trained in the processing step different from the target processing step.

16. A processing result estimation method for using processing conditions of a semiconductor manufacturing apparatus, which are configured by at least one step, as an input and outputting information indicating an estimated value of a processing result obtained by the processing conditions, the processing result estimation method comprising:
a learning step of training model parameters of an integrated model, which is a model obtained by integrating a step model and at least one step model that is a model in which a parameter value defined in the step is used as an input value, by using the integrated model and training data;
an estimation step of estimating information about the processing result according to a desired processing condition using the trained integrated model; and
an output step of outputting the estimated processing result,
wherein the integrated model outputs the information about the processing result by using a parameter value of the step corresponding to the step model as the input value, and
the information about the processing result acquired in advance includes information about the processing result obtained by two or more steps.

17. A search method for searching for a desired processing condition of a semiconductor manufacturing apparatus, which is configured by at least one step, the search method comprising:
a learning step of training model parameters of an integrated model, which is a model obtained by integrating a step model and at least one step model that is a model in which a parameter value defined in the step is used as an input value, by using the integrated model and training data;
an estimation step of estimating information about a processing result according to the desired processing condition using the trained integrated model; and
an output step of outputting the processing condition that is obtained by using the estimated processing result as a desired processing result,
wherein the integrated model outputs the information about the processing result by using a parameter value of the step corresponding to the step model as the input value, and
the information about the processing result acquired in advance includes information about the processing result obtained by two or more steps.

18. A server on which an application is implemented, the application using processing conditions of a semiconductor manufacturing apparatus, which are configured by at least one step, as an input and outputting information indicating an estimated value of a processing result obtained by the processing conditions,
wherein the application executes
a learning step of training model parameters of an integrated model, which is a model obtained by integrating a step model and at least one step model that is a model in which a parameter value defined in the step is used as an input value, by using the integrated model and training data,
an estimation step of estimating information about the processing result according to a desired processing condition using the trained integrated model, and
an output step of outputting the estimated processing result,
the integrated model outputs the information about the processing result by using a parameter value of the step corresponding to the step model as the input value, and
the information about the processing result acquired in advance includes information about the processing result obtained by two or more steps.
